(19) United States
(12) Patent Application Publication
(10) Pub. No.: US 2025/0318109 A1
(43) Pub. Date: Oct. 9, 2025

(54) SEMICONDUCTOR DEVICE INCLUDING ACTIVE REGIONS HAVING RECESSED PORTIONS

(71) Applicant: SK hynix Inc., Gyeonggi-do (KR)

(72) Inventor: Hyung Min KIM, Gyeonggi-do (KR)

(21) Appl. No.: 18/809,348

(22) Filed: Aug. 20, 2024

(30) Foreign Application Priority Data
Apr. 4, 2024 (KR) 10-2024-0045912

(51) Int. Cl. H10B 12/00

(52) U.S. Cl. CPC H10B 12/482; H10B 12/488

(57) ABSTRACT

A semiconductor device includes a plurality of gate lines extending in parallel with each other in a first horizontal direction; a plurality of bit lines extending in parallel with each other in a second horizontal direction; and a plurality of active regions having a bar shape elongated in a third horizontal direction and two dimensionally arranged. The first horizontal direction and the second horizontal direction are perpendicular to each other. The third horizontal direction diagonally intersects the first horizontal direction and the second horizontal direction. The active regions have recessed portions, respectively.

### CROSS-REFERENCE TO RELATED APPLICATIONS

The present application claims priority under 35 U.S.C 119 (a) to Korean Patent Application No. 10-2024-0045912, filed on Apr. 4, 2024, which is incorporated herein by reference in its entirety.

### BACKGROUND

### 1. Field

Embodiments of the present disclosure relate generally to a semiconductor device, and, more particularly, to a semiconductor device including active regions having recessed portions.

### 2. Description of the Related Art

The degree of integration of semiconductor devices is increased, and to improve the driving ability of gate electrodes, a gate structure with a buried channel array transistor structure having a saddle shaped fin type structure has been proposed.

### SUMMARY

An embodiment of the present disclosure provides a semiconductor device including active regions having recessed portions.

An embodiment of the present disclosure provides a gate structure having a buried fin structure having improved driving capability.

In accordance with an embodiment of the present disclosure, a semiconductor device includes a plurality of gate lines extending in parallel with each other in a first horizontal direction; a plurality of bit lines extending in parallel with each other in a second horizontal direction; and a plurality of active regions having a bar shape elongated in a third horizontal direction and two dimensionally arranged. The first horizontal direction and the second horizontal direction are perpendicular to each other. The third horizontal direction diagonally intersects the first horizontal direction and the second horizontal direction. The active regions have recessed portions, respectively.

In accordance with another embodiment of the present disclosure, a semiconductor device includes a plurality of gate lines extending in parallel with each other in a first direction; a plurality of bit lines extending in parallel with each other in a second direction; and first to third active regions sequentially arranged in the first direction. Each of the first to third active regions has a bar shape that is elongated in a third direction. The first direction and the second direction are perpendicular to each other. The third direction diagonally intersects the first direction and the second direction. An upper portion of the first active region and a lower portion of the second active region are disposed to have a first interval in the first direction. The lower portion of the second active region and an upper portion of the third active region are disposed to have a second interval in the first horizontal direction. The first interval is smaller than the second interval. The upper portion of the first active region and the lower portion of the second active region include recessed portions arranged to face each other in the first direction, respectively.

### BRIEF DESCRIPTION OF THE DRAWINGS

FIG. 1A is a layout of a cell region of a semiconductor device according to an embodiment of the present disclosure.

FIG. 1B is an enlarged view of an area in FIG. 1A.

FIG. 2A is a layout illustrating a conventional arrangement of conventional active regions.

FIG. 2B is a layout illustrating an arrangement of the active regions according to an embodiment of the present disclosure.

FIG. 3 is a longitudinal cross-sectional view of a cell region of a semiconductor device according to an embodiment of the present disclosure.

### DETAILED DESCRIPTION

Various embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, diverse embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

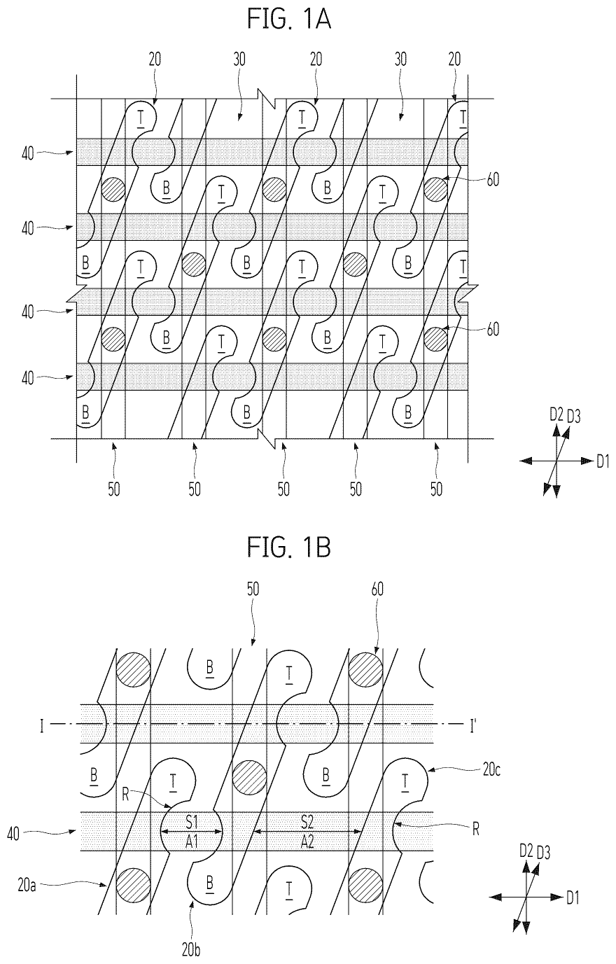

FIG. 1A is a layout of a cell region of a semiconductor device according to an embodiment of the present disclosure, and FIG. 1B is an enlarged view of an area in FIG. 1A. Referring to FIGS. 1A and 1B, a semiconductor device according to an embodiment of the present disclosure may include active regions 20, an STI (shallow trench isolation) region 30, gate lines 40, bit lines 50, and contact plugs 60.

The gate lines 40 may extend in parallel with each other in a first horizontal direction D1 (e.g., a row direction). The bit lines 50 may extend in parallel with each other in a second horizontal direction D2 (e.g., a column direction). The first horizontal direction D1 and the second horizontal direction D2 may be perpendicular to each other. Each of the active regions 20 may have a bar shape or a segment shape elongated in a third horizontal direction D3 (e.g., a diagonal direction). The third horizontal direction D3 may diagonally intersect the first horizontal direction D1 and the second horizontal direction D2. The STI region 30 may define the active regions 20. Each of the contact plugs 60 may be disposed on a central portion of a corresponding one of the active regions 20.

The active regions 20 may be two-dimensionally arranged. For example, the active regions 20 may be offset arranged in the first horizontal direction D1. The active regions 20 may be arranged spaced apart from each other in a zigzag configuration in the first horizontal direction D1. The active regions 20 may be arranged spaced apart from each other in the second horizontal direction D2. The active regions 20 may be arranged spaced apart from each other in the third horizontal direction D3 to be aligned on a straight line extending in the third horizontal direction D3. The active regions 20 may be repeatedly arranged so that the same shape is duplicated in the second horizontal direction D2 and the third horizontal direction D3, respectively.

Each of active regions 20 may intersect two gate lines 40 and one bit line 50. One of the two gate lines 40 may cross an upper portion T of one of the active regions 20 in the first horizontal direction D1, and the other one of the two gate lines 40 may cross a lower portion B of the one of the active regions 20 in the first horizontal direction D1. The bit line 50 may cross the central portion of the active region 20 in the second horizontal direction D2. Accordingly, each of the contact plugs 60 may be disposed to overlap each of the central portions of the corresponding active regions 20 and each of the bit lines 50, respectively.

The active regions 20 may be arranged so that first areas A1 (narrow areas) and second areas A2 (wide areas) may be alternately repeated in the first horizontal direction D1. The first area A1 may be a space between the active regions 20 disposed relatively close to each other in the first horizontal direction D1. The second area A2 may be a space between the active regions 20 disposed relatively far from each other in the first horizontal direction D1. Alternatively, the second area A2 may be a space between the active regions 20 in the third direction D3. For example, when first to third active regions 20a, 20b, and 20c are sequentially arranged in the first horizontal direction D1, the first area A1 may have a first interval between an upper portion T of the first active region 20a and a lower portion B of the second active region 20B which are adjacent to each other, and the second area A2 may have a second interval between a lower portion B of the second active region 20b and an upper portion T of the third active region 20c which are adjacent to each other. In the embodiments, the first area A1 and the second area A2 may be alternately and repeatedly arranged in the first horizontal direction D1. Accordingly, the first area A1 between the active areas 20a and 20b which are disposed relatively close to each other can be defined as an adjacent area, and the second area A2 between the active areas 20b and 20c which are disposed relatively far from each other can be defined as a spaced area. Stated differently, for each gate line 40, two active regions 20 that are separated from each other by the shorter area A1 may be referred to as a pair of horizontally adjacent active regions 20. Likewise, for each gate line 40, two active regions 20 that are separated from each other by the longer area A2 may be referred to as a pair of horizontally distantly (or remotely) adjacent active regions 20. Referring to FIG. 1B, the first active region 20a and the second active region 20b may be adjacent to each other on a first side (e.g., a left side) of the second active region 20b in the first horizontal direction D1. The second active region 20b and the third active region 20c may be remotely adjacent to each other on a second side (e.g., a right side) of the second active region 20b in the first horizontal direction D1. In another embodiment, the first side and the second side may be exchanged. For example, the active regions 20 in the drawings attached to the present disclosure may be arranged to have symmetry shapes left to right or up to down.

In the first area A1, the pair of the horizontally adjacent active regions 20a and 20b may have recessed portions R disposed to face each other. In the second area A2, the remotely adjacent active areas 20b and 20c which are more spaced apart from each other than the pair of the first and second active regions 20a and 20b may each have a flat side surface without any recessed portions. The first and second active regions 20a and 20b may be arranged in an offset arrangement or a zigzag arrangement in the first horizontal direction D1. The second and third active regions 20b and 20c may also be arranged in an offset arrangement or a zigzag arrangement in the first horizontal direction D1. The first and third active regions 20a and 20c may not be arranged in an offset arrangement or a zigzag arrangement in the first horizontal direction D1 and may be arranged in a duplicated arrangement or a repeated arrangement.

The recessed portions R may be formed on portions of the active regions 20 overlapping or substantially overlapping with the gate lines 40. That is, the recessed portions R may overlap with the gate lines 40. In an embodiment, the portions of the active regions 20 overlapping with the gate lines 40 may be recessed in the first horizontal direction D1. Each of the active regions 20 may include two recessed portions R positioned at opposite edge regions of each of the active regions 20. One of the two recessed portions R may be disposed in the upper portion T (or upper edge region) of each of the active regions 20a-20c, and the other one of the two recessed portions R may be disposed in the lower portion B (or lower edge region) of each of the active regions 20a-20c. Accordingly, the two recessed portions 20 may be disposed to overlap with different gate lines 40. The two recessed portions R of each of the active regions 20 may be disposed to be opposite to each other in the first horizontal direction D1. The two recessed portions R of each of the active regions 20 may be disposed to face away from each other or in opposite directions.

The recessed portions R of the pair of the horizontally adjacent active regions 20a and 20b in the first horizontal direction D1 may be recessed to face each other. By contrast, the recessed portions R of the pair of the remotely adjacent active regions 20b and 20c (also referred to as the spaced apart active regions) in the first horizontal direction D1 may be recessed to face away from each other or in opposite direction to each other. The first and second active regions 20a and 20b may be offset arranged so that the recessed portions R of the two horizontally adjacent active regions 20a and 20b may face each other. The second active region 20b and the third active region 20c may be offset arranged so that the recessed portions R of two active regions 20b and 20c to face away from each other or in opposite direction to each other. A facing direction and an opposite direction is defined based on a position where the recessed portions R are formed. The recessed portion R disposed in the upper portion T of the first active region 20a and the recessed portion R disposed in the lower portion B of the second active region 20b may commonly overlap with the same gate line 40.

The recessed portions R may have a semicircular or semi-elliptical shape. In some embodiments, the recessed portions R may have one of a polygonal shape, a bar shape, a dent shape, a notch shape, or a concave shape.

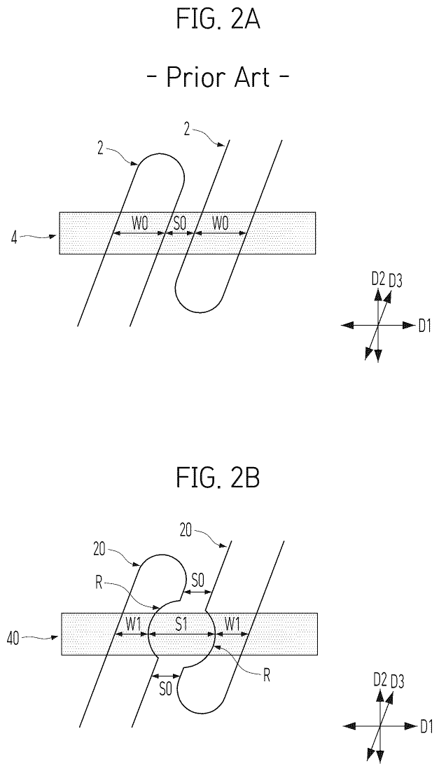

FIG. 2A is a layout illustrating an arrangement of conventional active regions 2 according to a conventional art. FIG. 2B is a layout illustrating an arrangement of the active regions 20 according to an embodiment of the present disclosure.

Referring to FIG. 2A, the conventional active regions 2 according to the conventional art do not have any recessed portions. The conventional active regions 2 have flat sides. The conventional active regions 2 are spaced apart from each other to have a conventional interval SO in an area overlapping with the gate line 4 in the first horizontal direction D1. The conventional active regions 2 may have a conventional width W0 in the area overlapping with the gate line 4 in the first horizontal direction D1.

Referring to FIG. 2B, the active regions 20 according to an embodiment of the present disclosure may have recessed portions R in an area overlapping or substantially overlapping with the gate line 40. The active regions 20 may be spaced apart from each other to have a first interval S1 in the area overlapping with the gate line 40 in the first horizontal direction D1. The first interval S1 may be greater than the conventional interval SO. The active regions 20 may have a first width W1 in the area overlapping with the gate line 40 in the first horizontal direction D1. The first width W1 may be smaller than the conventional width W0. In an area not overlapping with the gate line 40, the active regions 20 may have the conventional interval SO. That is, in a cell region of the semiconductor device according to an embodiment of the present disclosure, the conventional interval SO of the active regions 20 not overlapping with the gate line 40 may be smaller than the first interval S1 of the active regions 20 overlapping with the gate line 40. Due to the recessed portions R, the first interval S1 of the active regions 20 overlapping with the gate line 40 may be greater than the conventional interval SO.

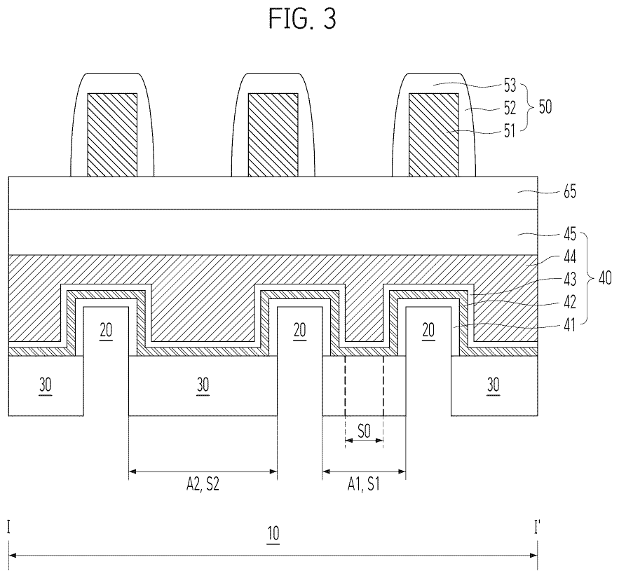

FIG. 3 is a longitudinal cross-sectional view of a cell region of a semiconductor device according to an embodiment of the present disclosure. For example, FIG. 3 is a longitudinal sectional view taken along the line I-I′ of FIG. 1B. Referring to FIG. 3, a semiconductor device according to an embodiment of the present disclosure may include active regions 20 protruding from a substrate 10, STI regions 30 between the active regions 20, a gate line 40 over the active regions 20 and the STI regions 30, and bit lines 50 over the gate line 40. The semiconductor device may further include an interlayer insulating layer 65 over the gate lines 40. The bit lines 50 may be disposed over the interlayer insulating layer 65. That is, the interlayer insulating layer 65 may be disposed between the gate lines 40 and the bit lines 50.

The substrate 10 may include a semiconductor material. For example, the substrate 10 may include one of a single crystalline silicon layer, an epitaxial growth layer, a semiconductor compound layer, or other semiconductor material layer. The active regions 20 may be protruding portions of the substrate 10. That is, the active regions 20 may be materially continuous with the substrate 10. That is, each of the active regions 20 may have a fin structure. The STI regions 30 may partially fill spaces between the active regions 20. The STI regions 30 may include an insulating material, e.g., silicon oxide or silicon nitride. In an embodiment or other longitudinal sectional view, the STI regions 30 may completely fill the spaces between the active regions 20. In an embodiment, the active regions 20 may be portions of the substrate 10, and the STI regions 30 may be material layers filling trenches formed in the substrate 20. The trenches may be formed between the active regions 20. Accordingly, the STI regions 30 may define the active regions 20.

Each of the gate lines 40 may include an interfacial insulating layer 41, a gate dielectric layer 42, a gate barrier layer 43, a gate electrode 44, and a gate capping layer 45.

The interfacial insulating layer 41 may be conformally disposed over the active regions 20. For example, the interfacial insulating layer 41 may include an oxidized silicon layer. The oxidized silicon layer may be formed by oxidizing surfaces of the active regions 20 exposed by the STI regions 30. In an embodiment, the interfacial insulating layer 41 may include silicon nitride.

The gate dielectric layer 42 may be conformally disposed over the interfacial insulating layer 41 and the STI region 30 to extend in the first horizontal direction D1. The gate dielectric layer 42 may include a high-k dielectric layer. For example, the gate dielectric layer 42 may include a metal oxide layer, e.g., a hafnium oxide layer, an aluminum oxide layer, or a zirconium oxide layer, a metal inorganic compound layer, e.g., a hafnium silicon oxide layer, a hafnium silicon oxide layer, a hafnium silicon oxide layer, or an aluminum oxide layer, or one of the combinations thereof.

The gate barrier layer 43 may be conformally disposed over the gate dielectric layer 42 and extend in the first horizontal direction D1. The gate barrier layer 43 may include at least one of a titanium nitride layer, a tantalum nitride layer, a tungsten nitride layer, a molybdenum nitride layer, a titanium silicide, a tantalum silicide, a tungsten silicide, a nickel silicide, a cobalt silicide, a molybdenum silicide, or a combination thereof.

In an embodiment, each of the gate lines 40 may further include a dipole layer disposed between the gate dielectric layer 42 and the gate barrier layer 43. The dipole layer may include a lanthanum oxide layer. The dipole layer may be conformally disposed over the gate dielectric layer 42 and extend in the first horizontal direction D1.

The gate electrode 44 may be disposed over the gate barrier layer 43 and extend in the first horizontal direction D1. The gate electrode 44 may include at least one of a doped polycrystalline silicon layer, a metal layer, a metal compound layer, and a metal alloy layer.

The gate capping layer 45 may be disposed over the gate electrode 44 and extend in the first horizontal direction D1. The gate capping layer 45 may include an insulating material layer such as silicon nitride.

Each of the gate lines 40 may be disposed in a gate trench. For example, each of the gate lines 40 may be formed in the gate trench extending in the first horizontal direction D1 to cross the active regions 20 and the STI regions 30.

The interlayer insulating layer 65 may be widely disposed on the gate lines 40. The interlayer insulating layer 65 may be formed in a plate shape in a top view. The interlayer insulating layer 65 may include at least one of a silicon oxide layer and a silicon nitride layer.

Each of the bit lines 50 may be disposed over the interlayer insulating layer 65. Each of the bit lines 50 may include a bit line electrode 51, a bit line spacer 52, and a bit line capping layer 53. The bit line electrode 51 may include a conductor. For example, the bit line electrode 51 may include at least one of a doped polycrystalline silicon layer, a metal layer, a metal compound layer, and a metal alloy layer. The bit line spacer 52 and the bit line capping layer 53 may include an insulating layer such as a silicon nitride layer or a silicon oxide layer. The bit line spacer 52 may surround side surfaces of the bit line electrode 51, and the bit line capping layer 53 may cover an upper surface of the bit line electrode 51. In an embodiment, each of the bit lines 50 may further include a bit line barrier layer surrounding at least a lower surface of the bit line electrode 51. The bit line barrier layer may further surround a side surface and/or an upper surface of the bit line electrode 51. The bit line barrier layer may include at least one of a titanium nitride layer, a tantalum nitride layer, a tungsten nitride layer, a molybdenum nitride layer, a titanium silicide layer, a tantalum silicide layer, a tungsten silicide layer, a nickel silicide layer, a cobalt silicide layer, or a combination thereof.

Referring to FIG. 1B, the first region A1 may have a first interval S1, and the second region A2 may have a second interval S2. Further referring to FIG. 2A, the active regions 2 according to the conventional art may be spaced apart from each other with the conventional interval S0. When intervals of the active regions 20 are narrow, for example, when the active regions 20 are spaced apart from each other with the conventional interval S0, the gate lines 40 are hard to form properly. Because the initial interval S0 is very narrow, the interfacial insulating layer 41, the gate dielectric layer 42, the gate barrier layer 43, and the gate electrode 44 cannot be formed properly. When the elements of the gate line 40 are not properly formed between the active regions 20, the driving ability of the gate line 40 declines, and the advantage of the fin gate structure is hard to achieve. Further referring to FIG. 2B, the interface insulating layer 41, the gate dielectric layer 42, the gate barrier layer 43, and the gate electrode 44 may be properly formed within the widened first interval S1. Accordingly, the driving ability of the gate line 40 is improved, and the advantages of the fin gate structure may be sufficiently utilized.

According to embodiments of the present disclosure, the interval between the active regions can be widened. Also, the present invention makes it easy to form a gate structure having a fin structure. Furthermore, performance of the gate structure can be improved. While the present disclosure has been described with respect to specific embodiments, it will be apparent to those skilled in the art that various changes and modifications may be made without departing from the technical concepts and scope of the present disclosure as defined in the following claims. Many other modifications, variations, and combinations of the described embodiments may be envisioned by the skilled person without departing from the scope of the present disclosure.

What is claimed is:

1. A semiconductor device comprising:
a plurality of gate lines extending in parallel with each other in a first horizontal direction;
a plurality of bit lines extending in parallel with each other in a second horizontal direction; and
a plurality of active regions having a bar shape elongated in a third horizontal direction and two dimensionally arranged,
wherein the first horizontal direction and the second horizontal direction are perpendicular to each other,
wherein the third horizontal direction diagonally intersects the first horizontal direction and the second horizontal direction, and
wherein the active regions have recessed portions, respectively.

2. The semiconductor device according to claim 1,
wherein the recessed portions overlap with the gate lines.

3. The semiconductor device according to claim 1,
wherein the recessed portions of two active regions adjacent to each other in the first horizontal direction face each other.

4. The semiconductor device according to claim 3,
wherein the recessed portions facing each other commonly overlap with a same one of the gate lines.

5. The semiconductor device according to claim 1,
wherein each of the active regions has two recessed portions.

6. The semiconductor device according to claim 5,
wherein one of the two recessed portions facing each other is disposed in an upper portion of one of the active regions adjacent to each other, and the other of the two recesses facing each other is disposed in a lower portion of the other of the active regions adjacent to each other, and
wherein the recessed portion disposed in the upper portion and the recessed portion disposed in the lower portion of the same one of the active regions are opposite to each other in the first horizontal direction.

7. The semiconductor device according to claim 5,
wherein the recessed portion in the upper portion and the recessed portion in the lower portion of the same active region overlap two gate lines adjacent to each other in the second horizontal direction, respectively.

8. The semiconductor device according to claim 1,
wherein the recessed portions are semicircular or semi-elliptical.

9. A semiconductor device comprising:
a plurality of gate lines extending in parallel with each other in a first direction;
a plurality of bit lines extending in parallel with each other in a second direction; and
first to third active regions sequentially arranged in the first direction, wherein each of the first to third active regions has a bar shape that is elongated in a third direction,
wherein the first direction and the second direction are perpendicular to each other,
wherein the third direction diagonally intersects the first direction and the second direction,
wherein an upper portion of the first active region and a lower portion of the second active region are disposed to have a first interval in the first direction,
wherein the lower portion of the second active region and an upper portion of the third active region are disposed to have a second interval in the first horizontal direction,
wherein the first interval is smaller than the second interval, and
wherein the upper portion of the first active region and the lower portion of the second active region include recessed portions arranged to face each other in the first direction, respectively.

10. The semiconductor device according to claim 9,
wherein each of the lower portion of the second active region and the upper portion of the third active region includes a recessed portion, and
wherein the recessed portions are arranged to be opposite to each other.

11. The semiconductor device according to claim 10,
wherein the recessed portions overlap with a same one of the gate lines.

12. The semiconductor device according to claim 9, wherein:
the first active region further includes a recessed portion disposed in a lower portion thereof,
the second active region further includes a recessed portion disposed in an upper portion thereof, and
the third active region further includes a recessed portion disposed in a lower portion thereof.

13. The semiconductor device according to claim 12,
wherein the recessed portions in the upper portions of the active regions and the recessed portions in the lower portions of the active regions are opposite to each other.

14. The semiconductor device according to claim 12,
wherein the recessed portions in the upper portions of the active regions and the recessed portions in the lower portions of the active regions overlap with the different gate lines.

15. The semiconductor device according to claim 14, further comprising:
active areas arranged in two dimensions each having a bar shape elongated in a diagonal direction,
wherein the active regions include a first active region, a second active region, and a third active region sequentially arranged in a row direction,
an upper portion of the first active region, a lower portion of the second active region, and an upper portion of the third active region each include a recessed portion recessed in the row direction,
wherein the recessed portion of the upper portion of the first active region and the recessed portion of the lower portion of the second active region face each other in the row direction.

16. The semiconductor device according to claim 15,
wherein the recessed portion of the lower portion of the second active region and the recessed portion of the upper portion of the third active region are arranged to be opposite to each other.

17. The semiconductor device according to claim 15,
wherein the recessed portion of the upper portion of the first active region and the recessed portion of the upper portion of the third active region are arranged in a same direction.

18. The semiconductor device according to claim 15, further comprising:
a gate line extending in the row direction,
wherein the gate line overlaps with the recessed portions in a top view.

19. The semiconductor device according to claim 15, wherein:
each of the active areas has two recessed portions,
wherein one of the recessed portions of each of the active areas is disposed in the upper portion of each of the active regions, and
wherein another one of the recessed portions of each of the active areas is disposed in the lower portion of each of the active regions.

20. The semiconductor device according to claim 19,
wherein the recessed portion disposed in the upper portion and the recessed portion disposed in the lower portion of one of the active regions are arranged to be opposite to each other.
